(19) United States
(12) Patent Application Publication
(10) Pub. No.: US 2011/0037069 A1
(43) Pub. Date: Feb. 17, 2011

(54) METHOD AND APPARATUS FOR VISUALLY DETERMINING ETCH DEPTH

(75) Inventors: Peter West, Minneapolis, MN (US); Dosi Dosev, Woodbury, MN (US)

Correspondence Address: KINNEY & LANGE, P.A., THE KINNEY & LANGE BUILDING, 312 SOUTH THIRD STREET, MINNEAPOLIS, MN, 55415-1002, US

(73) Assignee: Polar Semiconductor, Inc., Bloomington, MN (US)

(21) Appl. No.: 12/540,840

(22) Filed: Aug. 13, 2009

(51) Int. Cl. H01L 23/544; H01L 21/66

(52) U.S. Cl. 257/48; 438/16; 257/E23.179; 257/E21.53

(57) ABSTRACT

Etch depth of a material in a semiconductor wafer may be determined by forming a production region and a test region of the wafer, the test region having a test pattern for determining etch depth on a the wafer. The semiconductor wafer is comprised of a base layer, an intermediate layer above and visually distinguishable from the base layer, and a mask of photoresist material formed atop the intermediate layer. The mask of photoresist material has an areal photoresist coverage that varies across a horizontal axis. When the wafer is etched, a visible boundary can be seen between a region where the intermediate layer has been entirely etched away, and a region where at least some of the intermediate layer remains. The horizontal position of this visible boundary corresponds to the vertical etch depth in the production region., after etching of the semiconductor wafer.

### BACKGROUND

The present invention relates to measurement of surface etching depths, and more particularly to the etching of surfaces having at least two visibly distinguishable layers.

Integrated circuits typically comprise a substrate and one or more layers of material which form and electrically connect semiconductor devices formed on the substrate. These layers are first deposited uniformly on the substrate, and then patterned to form gates and other useful structures. This is done by forming a mask of photoresist material (which is eventually removed) over the layers, and etching away such regions of the layers as remain exposed. It is important in the formation of some semiconductor wafers that layers be entirely etched away in unmasked regions, without leaving any residue behind. Because of slight irregularities in the layers, such residue can seldom be completely removed without etching at least shallowly into an underlying layer or substrate. Etch depth is normally controlled by etching for a fixed time at a known rate, but etching is further complicated by the micro-loading effect, which slows etch rates on areas of the surface with a high local density of photoresist material.

Some popular etching methods exhibit poor selectivity between metallic layers and underlying substrate, and may easily over-etch deeply into the substrate. The target depth range for an etch, selected such that unprotected regions of the masked metallic layer are etched away while leaving the underlying substrate as undamaged as possible, is typically on the order of only 0.1 μm (micron). Measuring how deeply or quickly the substrate has been etched thus requires great precision.

Although it is usually possible to visually distinguish between etching on a masked layer and etching on the substrate, it is not possible to determine the depth of etching within a layer without more sophisticated techniques. A number of methods have been developed to measure etch depth. One common approach is to periodically sample wafers from production by splitting some wafers in cross-section, and directly measuring etch depth in the cross-section. This method gives a clear indication of etch depth, but requires the sacrifice of wafers to be cross-sectioned, and can therefore be costly. Another common technique is to fabricate simple test wafers, etch these wafers, and check the depth of this etching (by cross-sectioning or other means). This is less costly than cross-sectioning wafers from production, but only gives an approximation of the etch depth on actual production wafers, since test wafers and production wafers are not identical.

### SUMMARY

The present invention is directed towards methods and apparatus for determining etch depth of a material in a semiconductor wafer by forming a production region and a test region of the wafer, the test region having a test pattern for determining etch depth on a the wafer. The semiconductor wafer is comprised of a base layer, an intermediate layer above and visually distinguishable from the base layer, and a mask of photoresist material formed atop the intermediate layer. The mask of photoresist material has an areal photoresist coverage that varies across a horizontal axis. When the wafer is etched, a visible boundary can be seen between a region where the intermediate layer has been entirely etched away, and a region where at least some of the intermediate layer remains. The horizontal position of this visible boundary corresponds to the vertical etch depth in the production region., after etching of the semiconductor wafer.

### BRIEF DESCRIPTION OF THE DRAWINGS

FIG. 1 is a cross-section of an example pre-etching semiconductor wafer, illustrating the target etch depth.

FIG. 2 is a pre-etching overhead view of a test pattern for determining etch depth.

FIG. 3 is a pre-etching cross-section of the test pattern and a sample region of the target semiconductor wafer, taken along line 26-26 of FIG. 2.

FIG. 4 is a post-etching overhead view of the test pattern of FIG. 2.

FIG. 5 is a post-etching cross-section of the test pattern and a sample region of the target semiconductor wafer, taken along line 26-26 of FIG. 2.

FIG. 6 is a flowchart of the steps by which the test pattern of FIG. 2 is used to determine etch depth.

### DETAILED DESCRIPTION

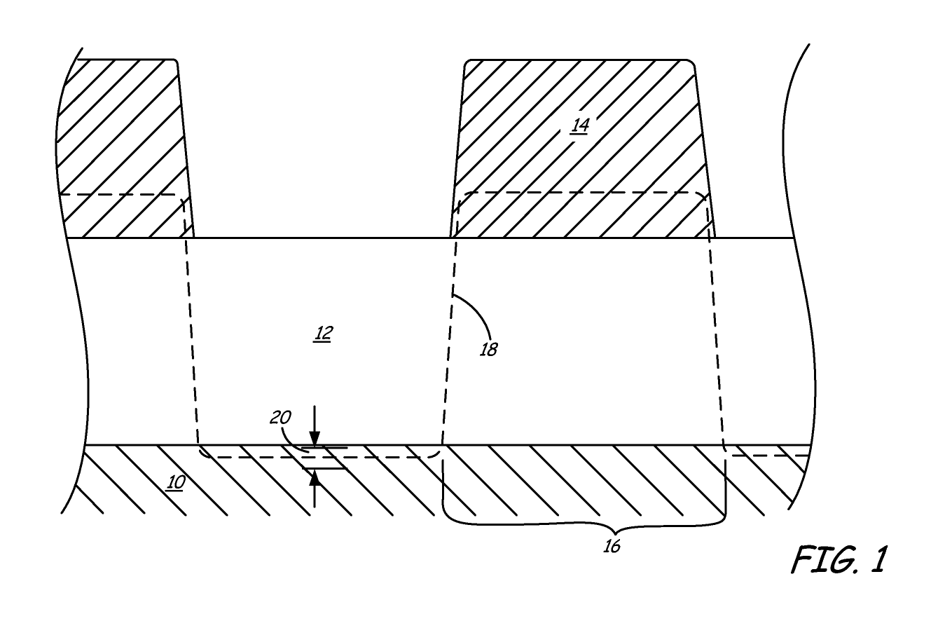

FIG. 1 is a cross-section of an example pre-etching semiconductor wafer, comprising base layer 10, intermediate layer 12, photoresist mask 14, masked region 16, target etch line 18, and target etch depth range 20.

Base layer 10 forms the lowest level of interest in the semiconductor wafer of FIG. 1, upon which intermediate layer 12 is formed of a semiconducting, insulating, or metallic material. Photoresist mask 14 is formed in a pattern on intermediate layer 12, shielding intermediate layer 12 from etchant where the mask is deposited. Masked region 16 illustrates one such shielded area; as can be seen from target etch line 18, the material of intermediate layer 12 will be entirely removed in areas not covered by photoresist mask 14, but will remain in areas such as masked region 16, which are protected by photoresist mask 14.

Target etch depth range 20 illustrates the range of acceptable etch depths (into which target etch line 18 falls). Target etch depth range 20 falls entirely, but shallowly, within base layer 10. Target etch depth range 20 will typically be quite narrow, on the order of 0.1 μm. Etching within this range requires precise control of etch depth.

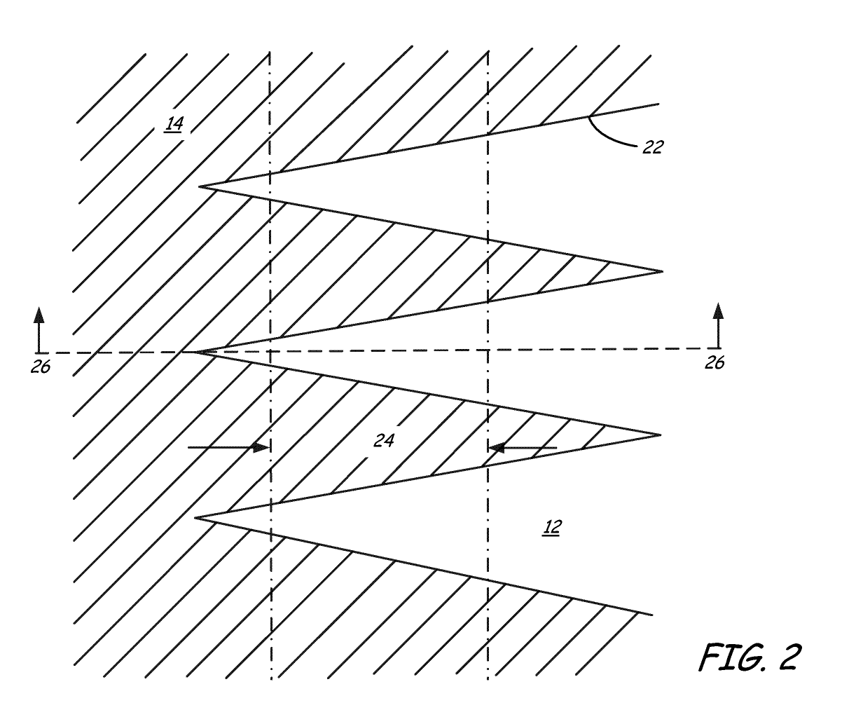

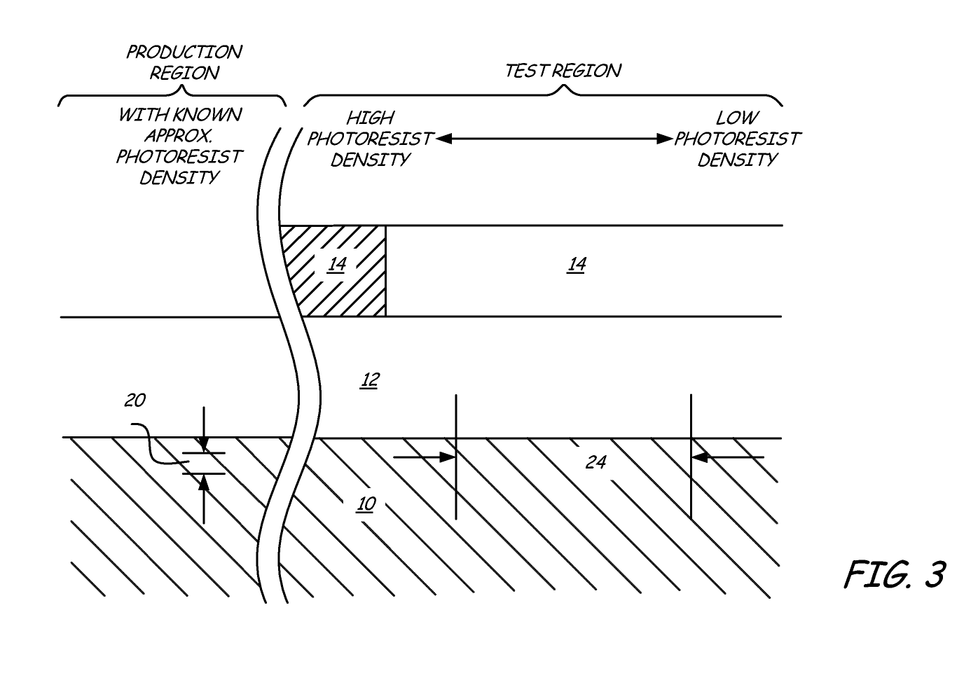

FIG. 2 provides an overhead view of an example pre-etching test region designed to enable precise measurement of etch depth. FIG. 2 illustrates intermediate layer 12, photoresist mask 14 formed in test pattern 22, horizontal range 24, and cutaway line 26-26. FIG. 3 is a cross-sectional view along cutaway line 26-26 of the pre-etching test region of FIG. 2, shown alongside an example section of the production wafer region. FIG. 3 shows base layer 10, intermediate layer 12, photoresist mask 14 formed in test pattern 22, target etch depth range 20, and horizontal range 24.

Precise measurement of etch rate and depth by visual means (typically with a simple optical microscope) without cross-sectioning of a wafer is made possible by the inclusion of test pattern 22 on an unused portion of the wafer. Photoresist mask 14 is formed atop intermediate layer 12 in test pattern 22, such that when the wafer is etched, exposed regions of intermediate layer 12 will etch more rapidly on one side of the pattern than the other, due to the micro-loading effect. The micro-loading effect occurs when photoresist mixes with etchant, locally slowing the etching process approximately linearly with the local areal density of photoresist. Because photoresist mask 14 provides high photoresist density on one side of the test region, and low photoresist density on the other, etching will occur slowly on the first side of the test region relative to the second.

The example sawtooth embodiment of test pattern 22 shown in FIG. 2 provides very high local density of photoresist material to the left, ranging linearly to low local density of photoresist material to the right. The material of photoresist mask 14 may also be deposited in a production pattern in the production region of the wafer.

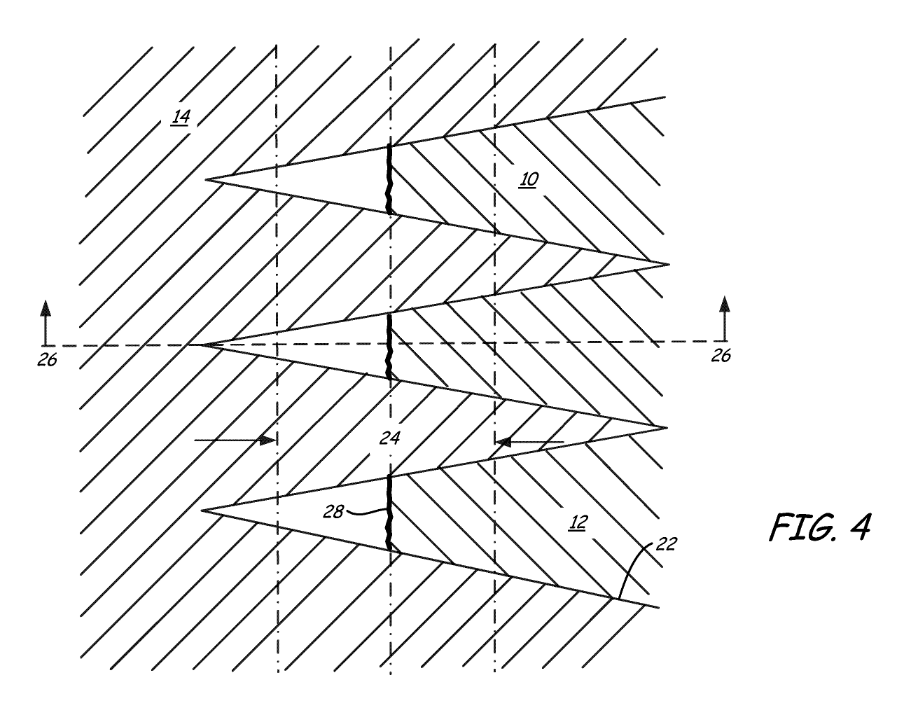

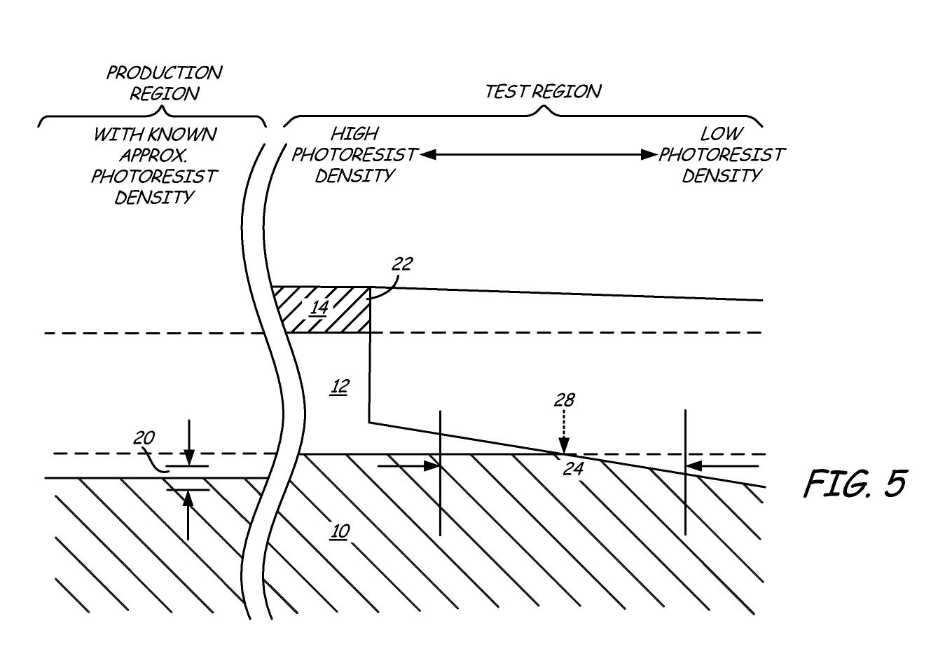

FIG. 4 is an overhead view of the example test region of FIG. 2, post-etching. FIG. 4. shows base layer 10, intermediate layer 12, photoresist mask 14 formed in test pattern 22, horizontal range 24, cutaway line 26-26, and visible boundary 28. FIG. 5 is a cross-sectional view along cutaway line 26-26 of the test region of FIG. 2, post-etching, shown alongside an example section of the production wafer region. FIG. 5 shows base layer 10, intermediate layer 12, photoresist mask 14 formed in test pattern 22, target etch depth range 20, horizontal range 24, and visible boundary 28.

Because of the linear variation in local photoresist density of test pattern 22 along cutaway line 26-26, the micro-loading effect retards etching strongly on the left side of the depicted example pattern, and very little on the right side of the pattern, such that exposed regions of intermediate layer 12 will be etched away first on the right side of the test region, and only later on the left side. Visible boundary 28 will develop between the region (to the right) where exposed regions of intermediate layer 12 will have been etched entirely away, exposing base layer 10, and the region (to the left) where some of unprotected masked layer 12 will remain. As etching continues, visible boundary 28 will move to the left, allowing etch depth at a region of interest on the wafer to be correlated with the location of visible boundary 28. This correlation between etch depth and visible boundary location enables horizontal range 24 to be defined to correspond to target etch depth range 20, such that whenever visible boundary 28 falls within horizontal range 24, the etch depth on the production wafer region will fall within target etch depth range 20 (see FIG. 5). In some embodiments, for example, the midpoint of horizontal range 28 will have slightly higher areal photoresist density than the production region.

There are multiple advantages of including test pattern 22 on an unused portion of the wafer. Since the horizontal position of visible boundary 28 is representative of the vertical etch depth on the production wafer region, direct measurement does not require cross-sectioning (and thereby destroying) the wafer. Also, in some embodiments, horizontal target range 24 can be on the order of 60 μm wide, 600 times the width of the vertical etch depth target range and therefore easier to measure with relative precision.

Test pattern 22 is sufficiently generic that it may be used for many different etches. Although changes in various parameters (such as the pattern of photoresist mask 14 over the production wafer region, materials, and target depth range) will affect the location of horizontal target range 24, the fundamental shape of test pattern 22 need not change. Although the embodiment of test pattern 22 depicted in FIGS. 2-5 is illustrative, other shapes may also be used. Any shape with a local area density of photoresist varying continuously or discretely will suffice.

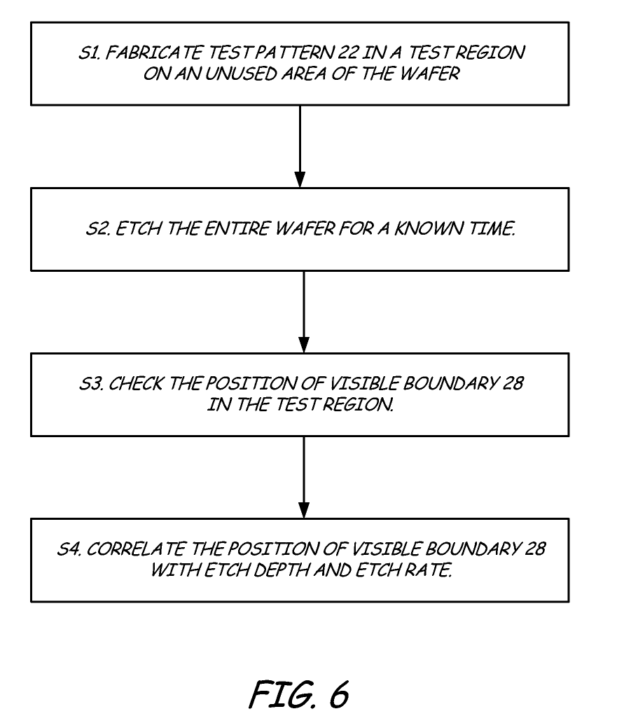

FIG. 6 is a flow diagram explaining the method by which test pattern 22 is used to determine etch depth. This method comprises the steps of fabricating test pattern 22 in a test region on an unused area of the wafer (step SI), etching the entire wafer for a known time (step S2), checking the position of visible boundary 28 in the test region (step S3), and correlating the position of visible boundary 28 with etch depth (step S4).

Step S1, “fabricating test pattern 22,” is accomplished as described above in the description of FIGS. 1-5. Test pattern 22 is designed to exhibit local photoresist area density which varies across the test region, and may include markings on the wafer to indicate horizontal range 24 for ease in later measurement. Step S2, “etching the entire wafer for a known time,” can be performed by any conventional etching technique which experiences a micro-loading effect. Step S3, “checking the position of visible boundary 28 in the test region,” involves determining where visible boundary 28 falls relative to horizontal range 24. This is accomplished as described above in the description of FIGS. 4-5, and is particularly straightforward if horizontal range 24 was marked on test pattern 22 as a part of step S1. If test pattern 22 is so marked, step S3 only requires reading the position of visible boundary 28 such as with an optical microscope. Step S4, “correlating the position of visible boundary 28 with etch depth and etch rate,” involves translating the position of visible boundary 28 into an etch depth, as determined by the shape of test pattern 22. In one embodiment, where local photoresist area density varies linearly across test pattern 22, and the magnitude of the micro-loading effect varies approximately linearly with photoresist area density, etch depth will be a linear function of the position of visible boundary 28, with slope and offset determined by the shape of test pattern 22.

The method and pattern herein described allow etch depth and to be measured precisely and nondestructively, with only simple equipment such as an optical microscope. Test pattern 22 is easily formed of photoresist mask layer 14, which is already used in the etching process, and correlating horizontal range 24 with target vertical etch depth 20 is simple.

While the invention has been described with reference to an exemplary embodiment(s), it will be understood by those skilled in the art that various changes may be made and equivalents may be substituted for elements thereof without departing from the scope of the invention. In addition, many modifications may be made to adapt a particular situation or material to the teachings of the invention without departing from the essential scope thereof. Therefore, it is intended that the invention not be limited to the particular embodiment(s) disclosed, but that the invention will include all embodiments falling within the scope of the appended claims.

1. A method for determining etch depth in an intermediate layer of material on a base layer of a semiconductor wafer that has a product portion and a test portion located separate from the product portion, the method comprising:
forming a photoresist test pattern mask over the intermediate layer of material on the test portion of the semiconductor wafer, the test pattern mask having an areal density that varies horizontally across the test portion of the semiconductor wafer;
etching the semiconductor wafer to at least partially remove unmasked regions of the intermediate layer of material in the product portion and the test portion of the semiconductor wafer, thereby creating a first region in the test portion in which the intermediate layer of material is completely removed and a second region in the test portion in which the intermediate layer of material is not completely removed, with a visible boundary therebetween;
visually checking a horizontal position of the visible boundary between the first region and the second region of the test portion; and
correlating the horizontal position of the visible boundary with etch depth of the intermediate layer of material in the product portion of the semiconductor wafer.

2. The method of claim 1, wherein the horizontal variation of the areal density of the test pattern mask is linear.

3. The method of claim 1, wherein the material is polysilicon.

4. (canceled)

5. The method of claim 1, wherein the base layer comprises an oxide layer.

6. The method of claim 1, wherein the visible boundary is distinguishable with an optical microscope.

7. A method for fabricating a semiconductor wafer having a production region and a test region for determining vertical etch depth, comprising the steps of:
forming, in both the test region and the production region of the wafer:
a base layer; and
an intermediate layer visually distinguishable from the base layer; and
forming a mask of photoresist material atop the intermediate layer in the test region of the wafer, wherein:
the mask of photoresist material has an areal density of photoresist coverage that varies across the wafer along a horizontal axis;
when the wafer is etched, a visible boundary can be seen between a region where the intermediate layer has been entirely etched away, exposing the base layer, and a region where at least some of the intermediate layer remains; and
the vertical etch depth of the intermediate layer in the production region is correlated with a horizontal position of the visible boundary between base layer and intermediate layer in the test region after etching the semiconductor wafer.

8. The method of claim 7, wherein the mask photoresist material is also deposited in a production pattern atop the intermediate layer in the production region of the wafer.

9. The method of claim 7, wherein the intermediate layer is comprised of polysilicon.

10. The method of claim 7, wherein the base layer is comprised of oxide.

11. The method of claim 7, wherein the horizontal variation of the areal density of the test pattern mask is linear.

12. A semiconductor wafer with a production region and a test region for determining vertical etch depth, comprising:
a base layer in both the production and test regions;
an intermediate layer in both the production and test regions, above and visually distinguishable from the base layer; and
a mask of photoresist material atop the intermediate layer in the test region, wherein:
the mask of photoresist material has an areal density of photoresist coverage that varies across the wafer along a horizontal axis;
when the wafer is etched, a visible boundary can be seen between a region where the intermediate layer has been entirely etched away, exposing the base layer, and a region where at least some of the intermediate layer remains; and
the vertical etch depth of the intermediate layer in the production region is correlated with a horizontal position of the visible boundary between base layer and intermediate layer in the test region after etching the semiconductor wafer.

13. The semiconductor wafer of claim 9, wherein the mask photoresist material is also deposited in a production pattern atop the intermediate layer in the production region of the wafer.

14. The semiconductor wafer of claim 9, wherein the intermediate layer is comprised of polysilicon.

15. The semiconductor wafer of claim 9, wherein the base layer is comprised of oxide.

16. The semiconductor wafer of claim 9, wherein the horizontal variation of the areal density of the test pattern mask is linear.
